(19) United States
(12) Patent Application Publication
(10) Pub. No.: US 2022/0137252 A1
(43) Pub. Date: May 5, 2022

(54) SPACE-TIME FRACTIONAL CONDUCTIVITY MODELING OF TWO-PHASE CONDUCTING MEDIA AND SIMULATION METHOD THEREOF

(71) Applicant: Jilin University, Changchun (CN)

(72) Inventors: Yanju JI, Changchun (CN); Xuejiao ZHAO, Changchun (CN); Yibing YU, Changchun (CN); Shipeng WANG, Changchun (CN); Jun LIN, Changchun (CN); Qiong WU, Changchun (CN); Dongsheng LI, Changchun (CN); Hui LUAN, Changchun (CN); Yuan WANG, Changchun (CN); Shanshan GUAN, Changchun (CN)

(21) Appl. No.: 17/190,445

(22) Filed: Mar. 3, 2021

(30) Foreign Application Priority Data
Oct. 29, 2020 (CN) 202011177685.9
Oct. 29, 2020 (CN) 202011177721.1

(51) Int. Cl. G01V 3/38; G01R 29/08; G01R 33/10; G01V 99/00

(52) U.S. Cl. CPC G01V 3/38; G01V 99/005; G01R 33/10; G01R 29/0892

(57) ABSTRACT

Provided is a space-time fractional conductivity modeling and simulation method of two-phase conducting media, including: 1) setting a simulated computation area, setting electric field or magnetic field distribution nodes in the simulated computation area, and setting an artificial current source at the origin of coordinates; 2) selecting a shape function in the entire computation area by a meshless method, and setting shape function parameters, Gaussian integral parameters, electromagnetic parameters, distance between the transmitting system and the receiving system, and the range of the frozen soil layer; 3) loading a first computation point and searching for nodes in the radius of the support domain, discretizing the definite integral by a 4-point Gaussian integral equation, then interpolating and summing to obtain the fractional derivative of the shape function, assigning the shape function result to the corresponding position of the large sparse matrix in the spatial fractional electric field diffusion equation.

### CROSS-REFERENCE TO RELATED APPLICATIONS

Pursuant to 35 U.S.C. § 119 and the Paris Convention Treaty, this application claims foreign priority to Chinese Patent Application No. 202011177685.9 filed on Oct. 29, 2020, and to Chinese Patent Application No. 202011177721.1 filed on Oct. 29, 2020. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, Mass. 02142.

### BACKGROUND

The disclosure relates to a space-time fractional conductivity modeling and simulation method of two-phase conducting media, which is suitable for the three-dimensional simulation of time domain electromagnetic multi-scale diffusion, especially for the high-precision three-dimensional numerical simulation of the induction and polarization effects caused by the complex geometric structure of the actual earth media.

In time domain transient electromagnetic methods, a long wire source or loop source is used to output time-varying current underground to excite the earth media to generate an induced electromagnetic field. By measuring electric or magnetic field signals, the electrical differences and the structure of the underground media are detected. As a non-uniform and strong dissipative medium, the earth's lithology and physical properties show high non-uniformity and non-linearity. Especially, resources such as concealed or disseminated polymetallic deposits, oil and gas reservoirs, composite oil and gas reservoirs, and geothermal energy are all composite multi-phase conducting media, so multi-scale measurement of complex physical features or parameters becomes especially important. Low-resistance and high-polarization anomalies are one of the important indicators for geophysical methods to detect sulfide-type, lead-zinc-silver and other polymetallic deposits, while high-resistance and high-polarization anomalies are important indicators for identification of oil and gas reservoirs. By the excitation of the alternating field, the induction and polarization effects in the multi-phase conducting media coexist and accompany each other. The induction response can better distinguish the geological formation, and the polarization response can effectively identify favorable oil and gas reservoirs and metal mine anomalies.

At present, the research on the polarization effect in China and abroad mainly focuses on the numerical calculation of the electromagnetic response of complex polarization bodies in the three-dimensional Cole-Cole model, and involves only the study of electromagnetic single-scale diffusion. However, there has been no relevant research on electromagnetic multi-scale diffusion. The Cole-Cole or GEMTIP model can characterize only the induction and polarization effects caused by the dispersion characteristics of the media. For the induction effect caused by the geometric structure in the oil and gas reservoirs and porous media, the existing models can no longer accurately extract information about resistivity.

### SUMMARY

The disclosure relates to a space-time fractional conductivity modeling and simulation method of two-phase conducting media. A space fractional term is introduced into the conductivity model of the two-phase conducting media to establish a multi-scale space-time fractional conductivity model, in which the time fractional term characterizes the porous polarization effect of the media and the space fractional term characterizes the induction response caused by the complex geometric structure of the media. The newly constructed conductivity model is introduced into an electromagnetic diffusion equation, and the time and space fractional differential terms are solved in the frequency domain using a combination of finite difference and meshless methods. Finally, the numerical simulation of the time domain multi-scale induction-polarization symbiosis effects of the electromagnetic field is completed by frequency-time conversion.

A space-time fractional conductivity modeling and simulation method of two-phase conducting media comprises:

1) setting a simulated computation area, setting electric field or magnetic field distribution nodes in the simulated computation area, and setting an artificial current source at the origin of coordinates;

2) selecting a shape function in the entire computation area by a meshless method, and setting shape function parameters, Gaussian integral parameters, electromagnetic parameters, distance between the transmitting system and the receiving system, and the range of the frozen soil layer;

3) loading a first computation point and searching for nodes in the radius of the support domain, discretizing the definite integral by a 4-point Gaussian integral equation, then interpolating and summing to obtain the fractional derivative of the shape function, assigning the shape function result to the corresponding position of the large sparse matrix in the spatial fractional electric field diffusion equation, selecting a next computation point until all computation points are processed to form a linear equation system for all nodes;

4) applying Dirichlet boundary conditions at the boundary of the computation area and selecting a frequency for the artificial current source, and solving the linear equation system by a LU decomposition method to obtain an electric field value at each node and obtain the magnetic field value of a corresponding node by a curl equation for the electric field; and

5) obtaining, by changing the emission frequency, the distribution of electric field and magnetic field values at different nodes and frequencies.

In a class of this embodiment, the electromagnetic parameters of numerical simulation comprise emission frequency, permeability, dielectric constant, ground conductivity, air conductivity and infinite frequency conductivity.

In a class of this embodiment, 3) comprises:

31) establishing a multi-scale space-time fractional conductivity model containing a time fractional term and a space fractional term;

32) transforming, by fractional operator transformation, the space fractional operator in the multi-scale space-time fractional conductivity model into a Laplacian operator of the electric field to obtain a fractional Laplacian operator, to obtain a spatial fractional electric field diffusion equation;

33) expanding, by the Caputo fractional definition, the spatial fractional electric field diffusion equation into a fractional differential form;

34) transforming, by a radial point interpolation meshless method, the second-order partial differential operation of the electric field into the second-order partial differential interpolation of a shape function, to complete the discretization of the differential term in the Caputo fractional order; and

35) transforming, by a Gaussian numerical integration method, the integral operation into Gaussian numerical integration accumulation, to complete the discretization of the integral term in the Caputo fractional order so that the spatial fractional electric field diffusion equation is transformed into a linear equation system about the electric field.

In a class of this embodiment, in 31), the established multi-scale space-time fractional conductivity model is expressed by:

$$σ ( ω ) = {{σ}_{0} ( i v )}^{a} ( 1 + {f}_{1} {M}_{1} [ 1 - \frac{1}{1 + {( i ω {τ}_{1} )}^{{C}_{1}}} ] + {f}_{2} {M}_{2} [ 1 - \frac{1}{1 + {( i ω {τ}_{2} )}^{{C}_{2}}} ] ) \qquad ( 1 )$$

In (1), σ(ω) is the conductivity in the frequency domain, i is the imaginary part, ω is the angular frequency, σ₀ is the value of the DC conductivity, f₁ is the volume fraction of the type-l particle, M₁ is the rock material property tensor, τ₁ is the time constant of the type-l particle, C₁ is the dispersion coefficient of the type-l particle, (iν)^{α} corresponds to the space fractional derivative for the Fourier mapping, ν is the dimensionless geometric factor, and α is the fractal dimension of the anomaly.

In a class of this embodiment, in 32), the multi-scale space-time fractional conductivity model expression (1) is substituted into the diffusion equation of the frequency domain electric field of the two-phase conducting media:

$${∇}^{2} E - {{σ}_{0} ( i v )}^{a} ( 1 + {f}_{1} {M}_{1} [ 1 - \frac{1}{1 + {( i {ωτ}_{1} )}^{{C}_{1}}} ] + {f}_{2} {M}_{2} [ 1 - \frac{1}{1 + {( i {ωτ}_{2} )}^{{C}_{2}}} ] ) ( i ω E ) = 0 \qquad ( 2 )$$

Both ends of equation (2) are multiplied by (iν)-^{α}:

$${( {∇}_{v}^{2} )}^{s} E - {σ}_{0} ( 1 + {f}_{1} {M}_{1} [ 1 - \frac{1}{1 + {( i {ωτ}_{1} )}^{{C}_{1}}} ] + {f}_{2} {M}_{2} [ 1 - \frac{1}{1 + {( i {ωτ}_{2} )}^{{C}_{2}}} ] ) ( i ω E ) = 0 \qquad ( 3 )$$

where

$$s = 1 - \frac{α}{2} ,$$

(∇_{ν}²)^{s} is the fractional Laplacian operator in dimensionless coordinates ν; the spatial fractional electric field diffusion equation is:

$${( {∇}_{v}^{2} )}^{s} E = \frac{{\partial }^{2 s} E}{\partial {x}^{2 s}} + \frac{{\partial }^{2 s} E}{\partial {y}^{2 s}} + \frac{{\partial }^{2 s} E}{\partial {z}^{2 s}} ; \qquad ( 4 )$$

where E represents the electric field, and x, y, and z each represent the deflection of the electric field in each direction.

In a class of this embodiment, in 33), by the Caputo fractional definition expansion, the space fractional differential term in the equation (4) is discretized and approximated:

$$\frac{{\partial }^{2 s} E}{\partial {u}^{2 s}} = \frac{1}{Γ ( 2 - 2 s )} {\int }_{a}^{u} \frac{{E}^{( 2 )} ( τ )}{{( u - τ )}^{2 s - 1}} d τ + \frac{1}{Γ ( 2 - 2 s )} {\int }_{u}^{b} \frac{{E}^{( 2 )} ( τ )}{{( u - τ )}^{2 s - 1}} d τ \qquad ( 5 )$$

where u=x, y or z, Γ is the gamma function, a is the lower limit of integration in the u direction, b is the upper limit of integration in the u direction, τ is the integral variable, and Γ(α) is the gamma function.

In a class of this embodiment, in 34), transforming, by a radial basis function meshless method, the second-order partial differential operation of the electric field into the second-order partial differential interpolation of a shape function to complete the discretization of the differential term in the Caputo fractional order in Equation (5) comprises:

$$\frac{{\partial }^{2 s} E}{\partial {u}^{2 s}} = {\sum }_{i = 1}^{n} [ \frac{1}{Γ ( 2 - 2 s )} {\int }_{a}^{u} \frac{{ϕ}_{ui}^{( 2 )} ( τ )}{{( u - τ )}^{2 s - 1}} d τ + \frac{1}{Γ ( 2 - 2 s )} {\int }_{u}^{b} \frac{{ϕ}_{ui}^{( 2 )} ( τ )}{{( τ - u )}^{2 s - 1}} d τ ] {E}_{i} \qquad ( 6 )$$

where Γ is the gamma function, Eᵢ is a number of interpolation nodes near E, ϕᵤᵢ is the corresponding interpolation shape function, ϕᵤᵢ⁽²⁾ is the interpolation shape function used to find the second-order partial derivative of u.

In a class of this embodiment, in 35), transforming, by a Gaussian numerical integration method, the integral operation into Gaussian numerical integration accumulation to complete the discretization of the integral term in the Caputo fractional order comprises:

first, transforming an integration interval into unit sub-units by coordinate transformation, wherein, if

$$τ = \frac{u - a}{2} η + \frac{u + a}{2} ,$$

then:

$$\frac{u - a}{{2}^{2 - 2 s}} {\int }_{- 1}^{1} \frac{{ϕ}_{i}^{( 2 )} ( \frac{u - a}{2} η + \frac{u + a}{2} )}{{( u - u η + a η - a )}^{2 s - 1}} d η \qquad ( 7 )$$

then, discretizing the integral term by the Gaussian numerical integration method:

$$\frac{u - a}{{2}^{2 - 2 s}} {\sum }_{k = 1}^{n} {A}_{k} \frac{{ϕ}_{i}^{( 2 )} ( \frac{u - a}{2} {η}_{k} + \frac{u + a}{2} )}{{( u - u {η}_{k} + a {η}_{k} - a )}^{2 s - 1}} \qquad ( 8 )$$

where ηₖ is the Gaussian integration point and Aₖ is the weight coefficient.

The disclosure also provides a device for geological exploration, the device comprising:

a computer, configured to simulate the distribution of electric and magnetic field values in different geological structures, different transmitting parameters and receiving distances, and different nodes and different frequencies;

a transient electromagnetic (TEM) detection system comprising a transmitting system and a receiving system; the transmitting system being configured, according to different geological structure characteristics and detection targets, to set the transmitting parameters and the receiving distance, based on the transmitting parameters and the receiving distance corresponding to the geological electric field value and magnetic field value under different frequencies simulated by the computer, and to transmit the current according to the transmitting parameters, and the receiving system being configured to synchronously collect the geological signal excited by the transmitting system.

In another aspect, the disclosure provides a method for setting of parameters of the device for geological exploration, the method comprising:

molding a geological structure, and simulating the distribution of electric and magnetic field values under different transmitting parameters and receiving distance, different nodes and different frequencies; and

according to the characteristics of geological structure and target to be detected, determining the transmitting parameters and receiving distance corresponding to the electric field value and magnetic field value of geology under different frequencies, and setting the transmitting parameters and receiving distance of TEM detection system.

The following advantages of the disclosure are associated with the method of the disclosure: a multi-scale space-time fractional conductivity model for complex rock structures is proposed, which can accurately describe the induction-polarization symbiosis effects of complex geometric structures. The fractional Laplacian operator is simplified by the Caputo fractional definition, to overcome the difficulty in solving the space fractional differential. Furthermore, the differential and integral terms are discretized respectively by the radial point interpolation meshless method and the Gaussian numerical integration method, which avoids too complex process, and provides a theoretical basis for the electromagnetic wave propagation mechanisms of complex geological structures.

### BRIEF DESCRIPTION OF THE DRAWINGS

FIG. 1 is a flowchart of a space-time fractional conductivity modeling and simulation method of two-phase conducting media;

FIG. 2 is a view comparing the numerical solution by the meshless method and the Mittag-Leffler function as the analytical solution, by taking a one-dimensional diffusion equation as an example;

FIG. 3 shows the influence of the fractal dimension on the received induced electromotive force; and

FIG. 4 shows the influence of the polarizability on the received induced electromotive force.

### DETAILED DESCRIPTION

To further illustrate the disclosure, embodiments detailing a space-time fractional conductivity modeling and simulation method of two-phase conducting media are described below. It should be noted that the following embodiments are intended to describe and not limit disclosure.

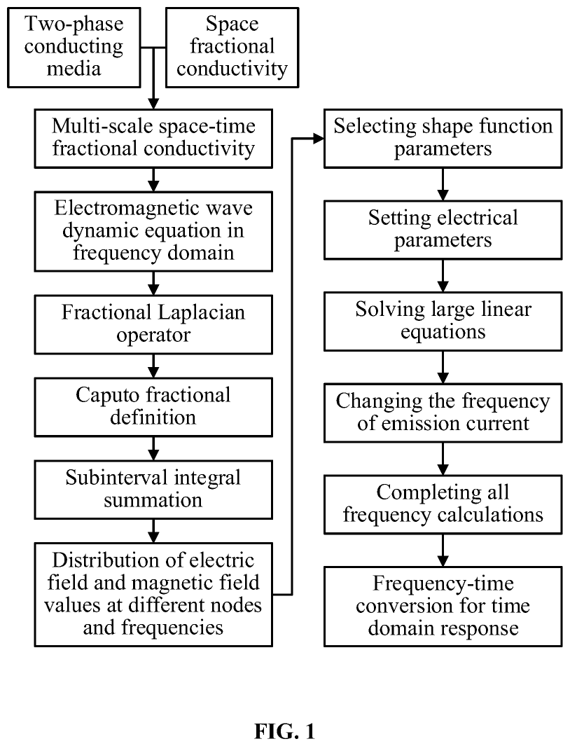

With reference to FIG. 1, a space-time fractional conductivity modeling and simulation method of two-phase conducting media comprises:

1) setting a simulated computation area, setting electric field or magnetic field distribution nodes in the simulated computation area, and setting an artificial current source at the origin of coordinates;

2) selecting a shape function in the entire computation area by a meshless method, and setting shape function parameters, Gaussian integral parameters, electromagnetic parameters, distance between the transmitting system and the receiving system, and the range of the frozen soil layer;

3) loading a first computation point and searching for nodes in the radius of the support domain, discretizing the definite integral by a 4-point Gaussian integral equation, then interpolating and summing to obtain the fractional derivative of the shape function, assigning the shape function result to the corresponding position of the large sparse matrix in the spatial fractional electric field diffusion equation, selecting a next computation point until all computation points are processed to form a linear equation system for all nodes;

4) applying Dirichlet boundary conditions at the boundary of the computation area and selecting a frequency for the artificial current source, and solving the linear equation system by a LU decomposition method to obtain an electric field value at each node and obtain the magnetic field value of a corresponding node by a curl equation for the electric field; and

5) obtaining, by changing the emission frequency, the distribution of electric field and magnetic field values at different nodes and frequencies; completing the numerical simulation of the time domain multi-scale induction-polarization symbiosis effects of the electromagnetic field by frequency-time conversion, saving data, plotting and analyzing the data.

3) comprises:

introducing a space fractional term into the conductivity model of the two-phase conducting media to establish a multi-scale space-time fractional conductivity model, wherein a time fractional term characterizes the multi-capacitance polarization effect of the media and a space fractional term characterizes the induction effect caused by the complex geometric structure;

transforming, by fractional operator transformation, the space fractional operation of the conductivity into a fractional Laplacian operator to obtain a space fractional electromagnetic diffusion equation;

expanding the fractional Laplacian operator in 2) into a fractional differential form, and discretizing the fractional differential in space by a Caputo fractional derivative;

transforming, by a radial point interpolation meshless method, the second-order partial differential operation of the electric field into the second-order partial differential interpolation of a shape function, to complete the discretization of the differential term in the Caputo fractional order;

transforming, by a Gaussian numerical integration method, the integral operation into Gaussian numerical integration accumulation, to complete the discretization of the integral term in the Caputo fractional order so that the fractional electromagnetic diffusion equation is transformed into a linear equation system about the electric field.

Specifically, the established multi-scale space-time fractional conductivity model is expressed by:

$$σ ( ω ) = {{σ}_{0} ( i v )}^{a} ( 1 + {f}_{1} {M}_{1} [ 1 - \frac{1}{1 + {( i ω {τ}_{1} )}^{{C}_{1}}} ] + {f}_{2} {M}_{2} [ 1 - \frac{1}{1 + {( i ω {τ}_{2} )}^{{C}_{2}}} ] ) \qquad ( 1 )$$

In (1), σ(ω) is the conductivity in the frequency domain, i is the imaginary part, ω is the angular frequency, σ₀ is the value of the DC conductivity, f₁ is the volume fraction of the type-l particle, M₁ is the rock material property tensor, τ₁ is the time constant of the type-l particle, C₁ is the dispersion coefficient of the type-l particle, (iν)^{α} corresponds to the space fractional derivative for the Fourier mapping, ν is the dimensionless geometric factor, and α is the fractal dimension of the anomaly.

The multi-scale space-time fractional conductivity model expression (1) is substituted into the diffusion equation of the frequency domain electric field of the two-phase conducting media:

$${∇}^{2} E - {{σ}_{0} ( i v )}^{a} ( 1 + {f}_{1} {M}_{1} [ 1 - \frac{1}{1 + {( i {ωτ}_{1} )}^{{C}_{1}}} ] + {f}_{2} {M}_{2} [ 1 - \frac{1}{1 + {( i {ωτ}_{2} )}^{{C}_{2}}} ] ) ( i ω E ) = 0 \qquad ( 2 )$$

Both ends of formula (2) are multiplied by (iν)-^{α}:

$${( {∇}_{v}^{2} )}^{s} E - {σ}_{0} ( 1 + {f}_{1} {M}_{1} [ 1 - \frac{1}{1 + {( i {ωτ}_{1} )}^{{C}_{1}}} ] + {f}_{2} {M}_{2} [ 1 - \frac{1}{1 + {( i {ωτ}_{2} )}^{{C}_{2}}} ] ) ( i ω E ) = 0 \qquad ( 3 )$$

where

$$s = 1 - \frac{α}{2} ,$$

(∇_{ν}²)² is the fractional Laplacian operator in dimensionless coordinates ν; the spatial fractional electric field diffusion equation is:

$${( {∇}_{v}^{2} )}^{s} E = \frac{{\partial }^{2 s} E}{\partial {x}^{2 s}} + \frac{{\partial }^{2 s} E}{\partial {y}^{2 s}} + \frac{{\partial }^{2 s} E}{\partial {z}^{2 s}} ; \qquad ( 4 )$$

where E represents the electric field, and x, y, and z each represent the deflection of the electric field in each direction.

By the Caputo fractional definition expansion, the space fractional differential term in the equation (4) is discretized and approximated:

$$\frac{{\partial }^{2 s} E}{\partial {u}^{2 s}} = \frac{1}{Γ ( 2 - 2 s )} {\int }_{a}^{u} \frac{{E}^{( 2 )} ( τ )}{{( u - τ )}^{2 s - 1}} d τ + \frac{1}{Γ ( 2 - 2 s )} {\int }_{u}^{b} \frac{{E}^{( 2 )} ( τ )}{{( u - τ )}^{2 s - 1}} d τ \qquad ( 5 )$$

where u=x, y or z, Γ is the gamma function, a is the lower limit of integration in the u direction, b is the upper limit of integration in the u direction, τ is the integral variable, and Γ(α) is the gamma function.

Transforming, by a radial basis function meshless method, the second-order partial differential operation of the electric field into the second-order partial differential interpolation of a shape function to complete the discretization of the differential term in the Caputo fractional order comprises:

$$\frac{{\partial }^{2 s} E}{\partial {u}^{2 s}} = {\sum }_{i = 1}^{n} [ \frac{1}{Γ ( 2 - 2 s )} {\int }_{a}^{u} \frac{{ϕ}_{ui}^{( 2 )} ( τ )}{{( u - τ )}^{2 s - 1}} d τ + \frac{1}{Γ ( 2 - 2 s )} {\int }_{u}^{b} \frac{{ϕ}_{ui}^{( 2 )} ( τ )}{{( τ - u )}^{2 s - 1}} d τ ] {E}_{i} \qquad ( 6 )$$

where Γ is the gamma function, Eᵢ is a number of interpolation nodes near E, ϕᵤᵢ is the corresponding interpolation shape function, ϕᵤᵢ⁽²⁾ is the interpolation shape function used to find the second-order partial derivative of u.

Transforming, by a Gaussian numerical integration method, the integral operation into Gaussian numerical integration accumulation to complete the discretization of the integral term in the Caputo fractional order comprises:

first, transforming an integration interval into unit sub-units by coordinate transformation, wherein, by taking equation (6) as an example, if

$$τ = \frac{u - a}{2} η + \frac{u + a}{2} ,$$

then:

$$\frac{u - a}{{2}^{2 - 2 s}} {\int }_{- 1}^{1} \frac{{ϕ}_{i}^{( 2 )} ( \frac{u - a}{2} η + \frac{u + a}{2} )}{{( u - u η + a η - a )}^{2 s - 1}} d η \qquad ( 7 )$$

then, discretizing the integral term by the Gaussian numerical integration method:

$$\frac{u - a}{{2}^{2 - 2 s}} {\sum }_{k = 1}^{n} {A}_{k} \frac{{ϕ}_{i}^{( 2 )} ( \frac{u - a}{2} {η}_{k} + \frac{u + a}{2} )}{{( u - u {η}_{k} + a {η}_{k} - a )}^{2 s - 1}} \qquad ( 8 )$$

where ηₖ is the Gaussian integration point and Aₖ is the weight coefficient.

The aforesaid method is implemented through a device for geological exploration, the device comprising:

a computer configured to simulate the distribution of electric and magnetic field values in different geological structures, different transmitting parameters and receiving distances, and different nodes and different frequencies; and

a transient electromagnetic (TEM) detection system comprising a transmitting system and a receiving system; the transmitting system being configured, according to different geological structure characteristics and detection targets, to set the transmitting parameters and the receiving distance, based on the transmitting parameters and the receiving distance corresponding to the geological electric field value and magnetic field value under different frequencies simulated by the computer, and to transmit the current according to the transmitting parameters, and the receiving system being configured to synchronously collect the geological signal excited by the transmitting system.

When in use, the parameters of the TEM detection system are set by the space-time fractional conductivity modeling and simulation method of two-phase conducting media. The parameters comprise transmitting parameters and receiving distance, and the setting process comprises:

molding a geological structure, and simulating the distribution of electric and magnetic field values under different transmitting parameters and receiving distance, different nodes and different frequencies; and

according to the characteristics of geological structure and target to be detected, determining the transmitting parameters and receiving distance corresponding to the electric field value and magnetic field value of geology under different frequencies, and setting the transmitting parameters and receiving distance of TEM detection system.

### EXAMPLE

With reference to FIG. 1, a space-time fractional conductivity modeling and simulation method of two-phase conducting media comprises:

1) setting a computation area (x: −40 km to 40 km, and z: −40 km to 40 km), in which total 101101=10201 nodes are uniformly distributed with a spacing of 800 m; and applying Dirichlet boundary conditions on four sides of the computation area, with an artificial current source arranged at (0 m, 0 m)

2) setting electromagnetic parameters in the entire computation area: emission frequency of 2n Hz(n=0,1,2, . . . ,10), permeability of 4π*10⁻⁷, dielectric constant of 1/36π*10⁻⁹, ground conductivity of 0.01 S/m, air conductivity of 1*10⁻⁶ S/m, c of 0.5, time constant of 0.01 s, infinite frequency conductivity of 0.1, frozen soil between 40 m and 120 m, and sending and receiving distance of 20 m;

3) setting parameters for the meshless method (including the selection of shape function types and the setting of shape function parameters and support domain parameters), initializing the large sparse matrix K (10201×10201 in size), loading a first computation point and searching for nodes in the radius of the support domain, interpolating to obtain a shape function, discretizing the definite integral by a 4-point Gaussian integral equation, then interpolating and summing to obtain the fractional derivative of the shape function, assigning the shape function result to the corresponding position of the large sparse matrix, selecting a next computation point from the nodes until all computation points are processed to form a linear equation system about the nodes, loading Dirichlet boundary conditions and a current source, solving the linear equation system by a LU decomposition method to obtain an electric field value at each node, and by changing the current emission frequency, obtaining the magnetic field values at different frequencies and then obtaining the magnetic field values by the curl equation for the electric field.

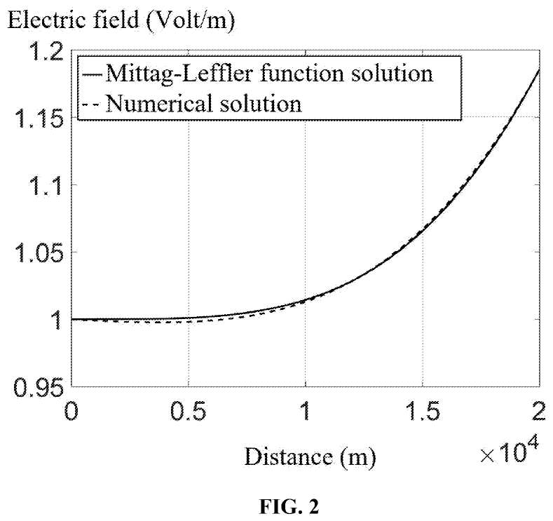

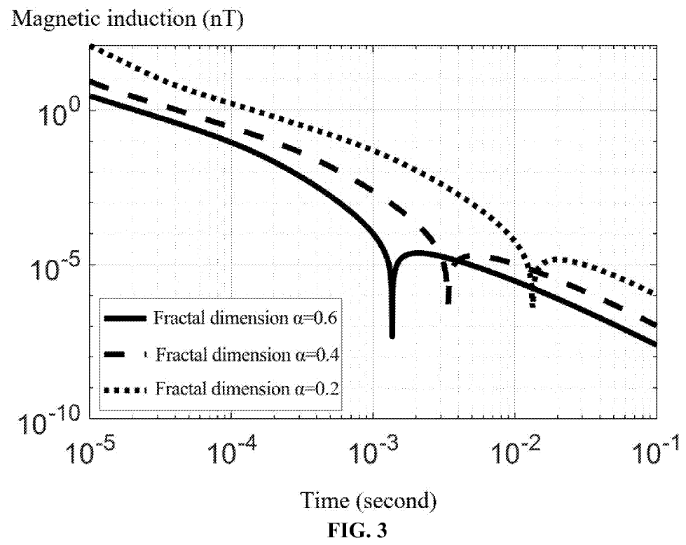

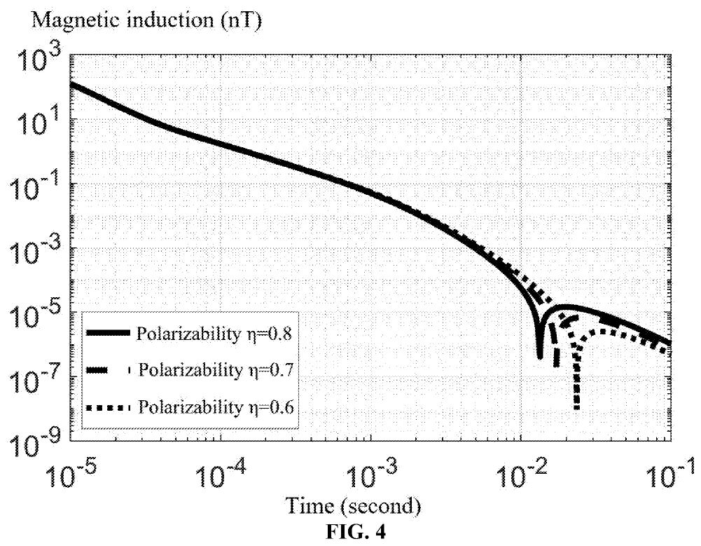

4) completing the numerical simulation of the time domain multi-scale induction-polarization symbiosis effects of the electromagnetic field by frequency-time conversion, saving data, and plotting. As shown in FIG. 2, the numerical solution by the meshless method and the Mittag-Leffler function as the analytical solution are basically consistent. As shown in FIG. 3, the fractal dimension influences the amplitude of the received induced electromotive force and the generation time of the opposite sign. The greater the fractal dimension, the smaller the response amplitude, and the earlier the generation of the opposite sign. As shown in FIG. 4, the polarizability influences the generation time of the opposite sign of the received induced electromotive force. The greater the polarizability, the earlier the generation of the opposite sign.

It will be obvious to those skilled in the art that changes and modifications may be made, and therefore, the aim in the appended claims is to cover all such changes and modifications.

What is claimed is:

1. A method, comprising:
1) setting a simulated computation area, setting electric field or magnetic field distribution nodes in the simulated computation area, and setting an artificial current source at an origin of coordinates;
2) selecting a shape function in the simulated computation area by a meshless method, and setting shape function parameters, Gaussian integral parameters, electromagnetic parameters, distance between a transmitting system and a receiving system, and a range of a frozen soil layer;
3) loading a first computation point and searching for nodes in a radius of a support domain, discretizing a definite integral by a 4-point Gaussian integral equation, then interpolating and summing to obtain a fractional derivative of a shape function, assigning a shape function result to a corresponding position of a large sparse matrix in a spatial fractional electric field diffusion equation, selecting a next computation point until all computation points are processed to form a linear equation system for all nodes;
4) applying Dirichlet boundary conditions at a boundary of the computation area and selecting a frequency for an artificial current source, and solving the linear equation system by a LU decomposition method to obtain an electric field value at each node and obtain a magnetic field value of a corresponding node by a curl equation for an electric field; and
5) obtaining, by changing an emission frequency, a distribution of electric field and magnetic field values at different nodes and frequencies.

2. The method of claim 1, wherein the electromagnetic parameters of numerical simulation comprise emission frequency, permeability, dielectric constant, ground conductivity, air conductivity and infinite frequency conductivity.

3. The method of claim 1, wherein 3) comprises:
31) establishing a multi-scale space-time fractional conductivity model containing a time fractional term and a space fractional term;
32) transforming, by fractional operator transformation, a space fractional operator in the multi-scale space-time fractional conductivity model into a Laplacian operator of the electric field to obtain a fractional Laplacian operator, to obtain the spatial fractional electric field diffusion equation;
33) expanding, by a Caputo fractional definition, the spatial fractional electric field diffusion equation into a fractional differential form;
34) transforming, by a radial point interpolation meshless method, a second-order partial differential operation of the electric field into a second-order partial differential interpolation of a shape function, to complete a discretization of a differential term in a Caputo fractional order; and
35) transforming, by a Gaussian numerical integration method, an integral operation into Gaussian numerical integration accumulation, to complete a discretization of an integral term in the Caputo fractional order so that the spatial fractional electric field diffusion equation is transformed into a linear equation system about the electric field.

4. The method of claim 3, wherein in 31), the established multi-scale space-time fractional conductivity model is expressed by:
$$σ ( ω ) = {{σ}_{0} ( i v )}^{α} ( 1 + {f}_{1} {M}_{1} [ 1 - \frac{1}{1 + {( i ω {τ}_{1} )}^{{C}_{1}}} ] + {f}_{2} {M}_{2} [ 1 - \frac{1}{1 + {( i ω {τ}_{2} )}^{{C}_{2}}} ] ) \qquad ( 1 )$$
in (1), σ(ω) is a conductivity in a frequency domain, i is an imaginary part, ω is an angular frequency, σ₀ is a value of a DC conductivity, f₁ is a volume fraction of a type-l particle, M₁ is a rock material property tensor, τ₁ is a time constant of the type-l particle, C₁ is a dispersion coefficient of the type-l particle, (iν)^{α} corresponds to a space fractional derivative for a Fourier mapping, ν is a dimensionless geometric factor, and α is a fractal dimension of an anomaly.

5. The method of claim 3, wherein in 32), the multi-scale space-time fractional conductivity model expression (1) is substituted into the diffusion equation of a frequency domain electric field of two-phase conducting media:
$${∇}^{2} E - {{σ}_{0} ( i v )}^{α} ( 1 + {f}_{1} {M}_{1} [ 1 - \frac{1}{1 + {( i ω {τ}_{1} )}^{{C}_{1}}} ] + {f}_{2} {M}_{2} [ 1 - \frac{1}{1 + {( i ω {τ}_{2} )}^{{C}_{2}}} ] ) ( i ω E ) = 0 \qquad ( 2 )$$
both ends of equation (2) are multiplied by (iν)-^{α}:
$${( {∇}_{v}^{2} )}^{s} E - {σ}_{0} ( 1 + {f}_{1} {M}_{1} [ 1 - \frac{1}{1 + {( i ω {τ}_{1} )}^{{C}_{1}}} ] + {f}_{2} {M}_{2} [ 1 - \frac{1}{1 + {( i {ωτ}_{2} )}^{{C}_{2}}} ] ) ( i ω E ) = 0 \qquad ( 3 )$$
where
$$s = 1 - \frac{α}{2} ,$$
(∇_{ν}²)² is the fractional Laplacian operator in dimensionless coordinates v; the spatial fractional electric field diffusion equation is:
$${( {∇}_{v}^{2} )}^{s} E = \frac{{\partial }^{2 s} E}{\partial {x}^{2 s}} + \frac{{\partial }^{2 s} E}{\partial {y}^{2 s}} + \frac{{\partial }^{2 s} E}{\partial {z}^{2 s}} \qquad ( 4 )$$
where E represents the electric field, and x, y, and z each represent a deflection of the electric field in each direction.

6. The method of claim 5, wherein in 33), by the Caputo fractional definition expansion, the space fractional differential term in equation (4) is discretized and approximated:
$$\frac{{\partial }^{2 s} E}{\partial {u}^{2 s}} = \frac{1}{Γ ( 2 - 2 s )} {\int }_{a}^{u} \frac{{E}^{( 2 )} ( τ )}{{( u - τ )}^{2 s - 1}} d τ + \frac{1}{Γ ( 2 - 2 s )} {\int }_{u}^{b} \frac{{E}^{( 2 )} ( τ )}{{( u - τ )}^{2 s - 1}} d τ \qquad ( 5 )$$
where u=x, y or z, Γ is a gamma function, a is a lower limit of integration in a u direction, b is an upper limit of integration in the u direction, τ is an integral variable, and Γ(α) is the gamma function.

7. The method of claim 6, wherein in 34), transforming, by a radial basis function meshless method, the second-order partial differential operation of the electric field into the second-order partial differential interpolation of a shape function to complete the discretization of the differential term in the Caputo fractional order in Equation (5) comprises:
$$\frac{{\partial }^{2 s} E}{\partial {u}^{2 s}} = {\sum }_{i = 1}^{n} [ \frac{1}{Γ ( 2 - 2 s )} {\int }_{a}^{u} \frac{{ϕ}_{ui}^{( 2 )} ( τ )}{{( u - τ )}^{2 s - 1}} d τ + \frac{1}{Γ ( 2 - 2 s )} {\int }_{u}^{b} \frac{{ϕ}_{ui}^{( 2 )} ( τ )}{{( τ - u )}^{2 s - 1}} d τ ] {E}_{i} \qquad ( 6 )$$
where Γ is the gamma function, Eᵢ is a number of interpolation nodes near E, ϕᵤᵢ is a corresponding interpolation shape function, ϕᵤᵢ⁽²⁾ is an interpolation shape function used to find a second-order partial derivative of u.

8. The method of claim 6, wherein in 35), transforming, by a Gaussian numerical integration method, the integral operation into Gaussian numerical integration accumulation to complete the discretization of the integral term in the Caputo fractional order comprises:
transforming an integration interval into unit sub-units by coordinate transformation, wherein, if
$$τ = \frac{u - a}{2} η + \frac{u + a}{2} ,$$
then:
$$\frac{u - a}{{2}^{2 - 2 s}} {\int }_{- 1}^{1} \frac{{ϕ}_{i}^{( 2 )} ( \frac{u - a}{2} η + \frac{u + a}{2} )}{{( u - u η + a η - a )}^{2 s - 1}} d η \qquad ( 7 )$$
discretizing the integral term by the Gaussian numerical integration method:
$$\frac{u - a}{{2}^{2 - 2 s}} {\sum }_{k - 1}^{n} {A}_{k} \frac{{ϕ}_{i}^{( 2 )} ( \frac{u - a}{2} {η}_{k} + \frac{u + a}{2} )}{{( u - u {η}_{k} + a {η}_{k} - a )}^{2 s - 1}} \qquad ( 8 )$$
where ηₖ is a Gaussian integration point and Aₖ is a weight coefficient.
